(19) United States
(12) Patent Application Publication
(10) Pub. No.: US 2006/0038243 A1
(43) Pub. Date: Feb. 23, 2006

(54) Transistor and method of manufacturing the same

(75) Inventors: Tetsuji Ueno, Suwon-si (KR); Dong-Suk Shin, Yongin-si (KR); Hwa-Sung Rhee, Sungnam-si (KR); Ho Lee, Gwangju-gun (KR); Seung-Hwan Lee, Seoul (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/071,018

(22) Filed: Mar. 3, 2005

(30) Foreign Application Priority Data
Aug. 20, 2004 (KR) 04-65736

(51) Int. Cl. H01L 29/76

(52) U.S. Cl. 257/408

(57) ABSTRACT

A transistor of the present invention includes a semiconductor substrate that has a first surface of the {100} crystal plane, a second surface of the {100} crystal plane having a height lower than that of the first surface, and a side face of the {111} crystal plane connecting the first surface to the second surface. A gate structure is formed on the first surface. An epitaxial layer is formed on the second surface and the side face. Impurity regions are formed adjacent to both sides of the gate structure. The impurity regions have side faces of the {111} crystal plane so that a short channel effect generated between the impurity regions may be prevented.

### CROSS REFERENCE TO RELATED APPLICATION

This application claims priority under 35 USC § 119 to Korean Patent Application No. 2004-65736 filed on Aug. 20, 2004, the contents of which are herein incorporated by reference in their entirety.

### BACKGROUND OF THE INVENTION

1. Field of the Invention

The present invention relates to a transistor and a method of manufacturing the transistor. More particularly, the present invention relates to a transistor including impurity regions that have improved characteristics, and a method of manufacturing the transistor.

2. Description of the Related Arts

In general, a transistor of a semiconductor device includes a gate structure formed on a semiconductor substrate, and source/drain regions provided at portions of the substrate adjacent to both sides of the gate structure. The gate structure includes a gate insulation layer pattern formed on the substrate, a conductive layer pattern formed on the gate insulation layer pattern, a hard mask layer pattern formed on the conductive layer pattern, and spacers formed on sidewalls of the conductive layer pattern.

The conductive layer pattern selectively forms a channel region in the substrate, which electrically connects the source region to the drain region. The source region provides carriers to the channel region, whereas the drain region discharges the carriers provided from the source region.

In the conventional transistor, an interface between the source/drain regions and the substrate may be damaged due to a hot carrier effect caused by rapid electrons. To prevent the hot carrier effect, there is provided a method of forming source/drain regions having lightly doped drain (LDD) structures. However, in a process for forming the LDD structures, impurities may diffuse into the substrate to thereby reduce a width of the channel region while the impurities are thermally treated to form the source/drain regions. As a semiconductor device has been highly integrated, the width of the channel region has been additionally reduced. This is referred to as a short channel effect. When the width of the channel region is reduced, a depletion layer adjacent to the source region may be electrically connected to a depletion layer adjacent to the drain region so that punch-through may occur in the transistor. Punch-through is a phenomenon in which the carriers move between the source region and the drain region through the channel region although a threshold voltage is not applied to the conductive layer pattern. When punch-through occurs in the transistor, the transistor may fail completely.

To prevent the short channel effect in the LDD structures, a method of forming a semiconductor device having a single drain cell structure is disclosed in U.S. Pat. No. 6,599,803 and U.S. Pat. No. 6,605,498. According to the method disclosed in the above U.S Patents, recesses are formed at both sides of a gate electrode. Epitaxial layers including silicon-germanium grow in the recesses to form the single drain cell structure. In addition, a method of forming a semiconductor device is disclosed in Korean Patent Laid Open Publication No. 2003-82820. According to the method disclosed in the above Korean Patent Laid Open Publication, trenches are formed at both sides of a gate electrode. Spacers including insulating material are formed in the trenches under sidewalls of the gate electrode.

The above-mentioned conventional methods of forming a transistor having the single drain cell structure may have some advantages such as a relatively low resistance, a steep PN junction, a reduced thermal budget, etc. Thus, the conventional methods of forming a transistor may be employed for a transistor having a gate width of below about 100 nm.

However, the transistor formed by the conventional methods still have characteristics that can be improved upon, such as a lower resistance, a more steep PN junctions, etc. Therefore, the conventional method may not be easily employed for a highly integrated transistor having a gate width of below about 10 nm.

### SUMMARY OF THE INVENTION

The present invention provides a highly integrated transistor including an improved structure that has excellent electrical characteristics.

The present invention also provides a method of forming the transistor.

In accordance with one aspect of the present invention, there is provided a transistor including a semiconductor substrate that has a first surface of a {100} crystal plane, a second surface of the {100} crystal plane having a height lower than that of the first surface, and a side face of a {111} crystal plane connecting the first surface to the second surface. A gate structure is formed on the first surface. An epitaxial layer is formed on the second surface and the side face. Impurity regions are formed adjacent to both sides of the gate structure.

In one embodiment, the gate structure comprises a gate insulation layer pattern formed on the first surface and a conductive pattern formed on the gate insulation layer pattern.

The transistor of the invention can further include a hard mask layer pattern formed on the conductive layer pattern. The transistor of the invention can further include a spacing member formed on a sidewall of the conductive layer pattern. The side face can be positioned beneath the spacing member. The spacing member can include a first spacer formed on the sidewall of the conductive layer pattern and a second spacer formed on the first spacer. The first and second spacers can include a substantially identical material. The first and second spacers can include a nitride.

In one embodiment, the epitaxial layer comprises silicon-germanium.

According to one embodiment of the present invention, the impurity regions have side faces substantially corresponding to the side face of the semiconductor substrate. Alternatively, each impurity region may have a side face disposed between a central portion of the gate structure and the side face of the semiconductor substrate.

In one embodiment, the impurity regions are doped with carbon, boron or phosphorous.

According to another embodiment of the present invention, a halo implantation region is formed at a portion of the semiconductor substrate that makes contact with the side face of the semiconductor substrate. The halo implantation region prevents impurities doped into the impurity regions from diffusing into the semiconductor substrate. The halo implantation region can include a conductive type substantially different from those of the impurity regions.

In one embodiment, the epitaxial layer comprises a first crystalline structure growing from the side face of the {111} crystal plane in the [111] direction, and a second crystalline structure growing from the second surface of the {100} crystal plane in the [100] direction.

The epitaxial layer can include a surface higher than the first surface of the semiconductor substrate.

In accordance with another aspect of the present invention, there is provided a transistor including a semiconductor substrate that has a first surface of a {100} crystal plane, two second surfaces of the {100} crystal plane positioned at both sides of the first surface, and two side faces of a {111} crystal plane connecting the first surface to the second surfaces, respectively. The second surfaces have heights lower than that of the first surface. A gate structure is formed on the first surface. Two epitaxial layers are formed on the second surfaces and the side faces, respectively. Two impurity regions are formed in the epitaxial layers, respectively.

In one embodiment, spacing members are formed on sidewalls of the gate pattern, respectively. In one embodiment, the side faces are beneath the spacing members. The epitaxial layers can comprise silicon-germanium.

In one embodiment, the impurity regions comprise side faces substantially corresponding to the side faces of the semiconductor substrate.

In one embodiment, the impurity regions comprise side faces between the side faces of the semiconductor substrate and a central portion of the gate structure. The impurity regions can be doped with carbon, boron or phosphorous.

The transistor can further include halo implantation regions respectively formed at portions of the semiconductor substrate that make contact with the side faces of the semiconductor substrate, the halo implantation regions preventing impurities in the impurity regions from diffusing into the semiconductor substrate. The halo implantation regions can comprise conductivity types substantially different from those of the impurity regions.

In one embodiment, the epitaxial layers comprise first crystalline structures growing from the side faces of the {111} plane in the [111] direction, and second crystalline structures growing from the second surfaces of the {100} plane in the [100] direction.

The epitaxial layers can comprise surfaces higher than the first surface of the semiconductor substrate.

In accordance with still another aspect of the present invention, there is provided a method of manufacturing a transistor. In the method of manufacturing the transistor, there is provided a semiconductor substrate including a first surface of a {100} crystal plane, a second surface of the {100} crystal plane having a height lower than that of the first surface, and a side face of a {111} crystal plane connecting the first surface to the second surface. A gate structure is formed on the first surface. An epitaxial layer grows on the second surface and the side face. Impurities are implanted into the epitaxial layer to form impurity regions.

In one embodiment, forming the gate structure comprises forming a gate insulation layer pattern on the first surface and forming a conductive pattern on the gate insulation layer pattern.

The method can further comprise forming a hard mask layer pattern on the conductive layer pattern.

The method can further comprise forming a spacing member on a sidewall of the conductive layer pattern. The side face can be positioned beneath the spacing member. Forming the spacing member can comprise: forming a first spacer on the sidewall of the conductive layer pattern; and forming a second spacer on the first spacer. The first and second spacers can comprise a substantially identical material. The first and second spacers comprise a nitride.

In one embodiment, the second surface and the side face are formed by partially etching the semiconductor substrate. The semiconductor substrate can be partially etched using an etching gas that includes HCl and at least one of GeH₄, SiH₄ and SiH₂Cl₂. The semiconductor substrate can be partially etched at a temperature of about 500 to about 700° C. In one embodiment, the method further comprises, prior to partially etching the semiconductor substrate, implanting halo dopants into the semiconductor substrate to form a preliminary halo implant region, and partially removing the preliminary halo implantation region during partially etching the semiconductor substrate to form a halo implantation region making contact with the side face of the semiconductor substrate, the halo implantation region preventing the impurities from diffusing into the semiconductor substrate. In one embodiment, the halo dopants comprise conductivity types substantially different from those of the impurity regions.

In one embodiment, the epitaxial layer comprises silicon-germanium.

In one embodiment, the epitaxial layer comprises a first crystalline structure growing from the side face of the {111} plane in the [111] direction, and a second crystalline structure growing from the second surface of the {100} plane in the [100] direction.

In one embodiment, the epitaxial layer comprises a surface higher than the first surface of the semiconductor substrate.

In one embodiment, implanting the impurities and growing the epitaxial layer are simultaneously performed.

In one embodiment, the impurities comprise carbon, boron or phosphorous.

According to one embodiment of the present invention, before etching the semiconductor substrate to form the second surface and the side face, halo dopants are implanted into the semiconductor substrate to form a preliminary halo implantation region. The preliminary halo implantation region is partially removed during the etching process to form a halo implantation region making contact with the side face, thereby preventing the impurities from diffusing into the semiconductor substrate.

According to another embodiment of the present invention, the impurities are implanted into the semiconductor substrate while the epitaxial layer grows.

In accordance with still another aspect of the present invention, there is provided a method of manufacturing a transistor. In the method of manufacturing the transistor, a gate pattern is formed on a surface of a {100} crystal plane of a semiconductor substrate. A first spacer is formed on a sidewall of the gate pattern. A second spacer is formed on the first spacer. Portions of the semiconductor substrate adjacent to both sides of the gate pattern are partially etched to form a recess exposing a portion of the gate pattern and the first and second spacers. The recess has a bottom face of the {100} crystal plane having a height lower than that of the surface, and a side face of a {111} crystal plane connecting the surface to bottom face. An epitaxial layer grows to fill up the recess. Impurities are then implanted into the epitaxial layer to form impurity regions.

In one embodiment, the side face is positioned beneath the first and second spacers.

In one embodiment, the method further comprises, prior to forming the second spacer, implanting halo dopants into the semiconductor substrate using the first spacer as an ion implantation mask to form a preliminary halo implantation region, and partially removing the preliminary halo implantation region during forming the recess to form a halo implantation region making contact with the side face, the halo implantation region preventing the impurities from diffusing into the semiconductor substrate.

In one embodiment, etching the portions of the semiconductor substrate is carried out using an etching gas that includes HCl and at least one of GeH₄, SiH₄ and SiH₂Cl₂.

In one embodiment, etching the portions of the semiconductor substrate is performed at a temperature of about 500 to about 700° C.

In one embodiment, the epitaxial layer comprises a surface higher than the surface of the semiconductor substrate.

In one embodiment, the epitaxial layer comprises silicon-germanium.

In one embodiment, implanting the impurities and growing the epitaxial layer are simultaneously performed.

In accordance with still another aspect of the present invention, there is provided a method of manufacturing a transistor. In the method of manufacturing the transistor, a gate pattern is formed on a surface of a {100} crystal plane of a semiconductor substrate. First spacers are formed on sidewalls of the gate pattern. Portions of the semiconductor substrate adjacent to both sides of the gate pattern are partially etched to form recesses exposing a portion of the gate pattern and the first spacer. The recesses have bottom faces of the {100} crystal plane having heights lower than that of the surface, and side faces of a {111} crystal plane connecting the surface to bottom faces. Epitaxial layers are grown to fill up the recesses. Second spacers are formed on the first spacers and the epitaxial layers. Impurities are then implanted into the epitaxial layers to form impurity regions.

In one embodiment, the method further comprises, prior to etching the portions of the semiconductor substrate, implanting halo dopants into the semiconductor substrate using the first spacers as ion implantation masks to form preliminary halo implantation regions, and partially removing the preliminary halo implantation regions during forming the recesses to form halo implantation regions making contact with the side faces of the recesses, the halo implantation regions preventing the impurities from diffusing into the semiconductor substrate. In one embodiment, the epitaxial layers comprise surfaces higher than the surface of the semiconductor substrate.

According to the present invention, since the impurity regions have side faces of the {111} crystal plane, a PN junction may be steeply formed. Thus, generating a short channel effect between the impurity regions may be prevented so that a transistor having improved electrical characteristics is obtained.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thicknesses of layers are exaggerated for clarity.

FIG. 1 is a cross sectional view illustrating a transistor in accordance with a first embodiment of the present invention.

FIGS. 2 to 5 are cross sectional views illustrating a method of forming the transistor in FIG. 1.

FIGS. 6 and 7 are cross sectional views illustrating a method of forming a transistor in accordance with a second embodiment of the present invention.

FIGS. 8 to 12 are cross sectional views illustrating a method of forming a transistor in accordance with a third embodiment of the present invention.

FIG. 13 is a cross sectional view illustrating a transistor in accordance with a fourth embodiment of the present invention.

FIGS. 14 to 18 are cross sectional views illustrating a method of forming the transistor in FIG. 13.

FIGS. 19 and 20 are cross sectional views illustrating a method of forming a transistor in accordance with a fifth embodiment of the present invention.

FIGS. 21 to 26 are cross sectional views illustrating a method of forming a transistor in accordance with a sixth embodiment of the present invention.

FIG. 27 is a cross sectional view illustrating a transistor in accordance with a seventh embodiment of the present invention.

### DESCRIPTION OF THE EMBODIMENTS

The present invention now will be described more fully hereinafter with reference to the accompanying drawings, in which embodiments of the invention are shown. It will be understood that when an element such as a layer, region or substrate is referred to as being “on” or “onto” another element, it can be directly on the other element or intervening elements may also be present.

### Embodiment 1

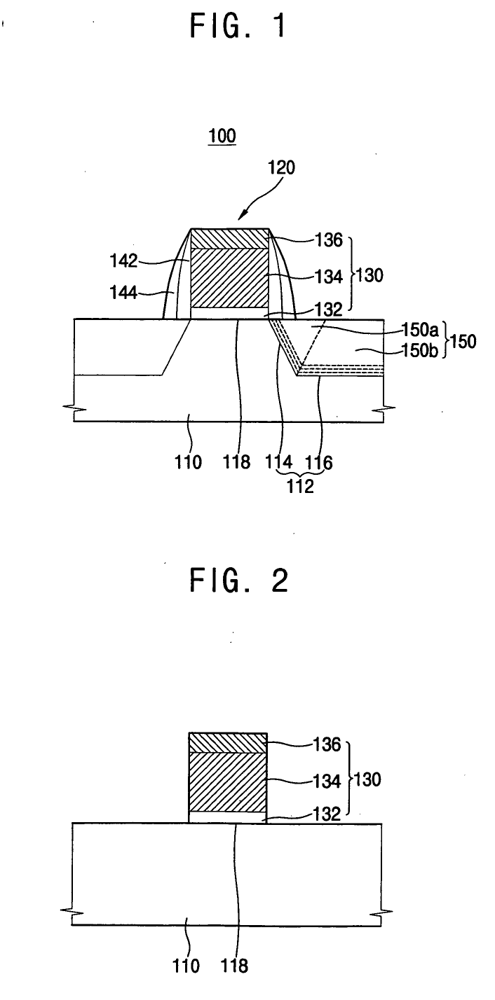

FIG. 1 is a cross sectional view illustrating a transistor in accordance with a first embodiment of the present invention.

Referring to FIG. 1, a transistor 100 of the present embodiment includes a semiconductor substrate 110 such as a silicon (Si) substrate or a silicon-germanium (Si—Ge) substrate, a gate structure 120 formed on the semiconductor substrate 110, two epitaxial layers 150 formed at portions of the semiconductor substrate 110 adjacent to the gate structure 120, and impurity regions respectively formed in the epitaxial layers 150.

The semiconductor substrate 110 has a surface 118 including silicon oriented along the {100} crystal plane. The gate structure 120 is formed on the surface 118 of the substrate 110.

Two recesses 112 are respectively formed at portions of the surface 118 adjacent to the gate structure 120. The recesses 112 include bottom faces 116 and side faces 114, respectively. The bottom faces 116 include silicon oriented along the {100} plane, whereas the side faces 114 include silicon oriented along the {111} plane. Each of the bottom faces 116 has a height substantially less than that of the surface 118 of the substrate 110. Each of the side faces 114 is between the bottom face 116 and the surface 118 to connect the bottom face 116 to the surface 118. Since the side face 114 of the {111} plane is positioned, an angle between the side face 114 and the bottom face 116 is about 54.7°. For example, the angle may be no less than about 50° or about 54.7° in processes for forming the transistor 100. When the angle between the side face 114 and the bottom face 116 is preferably in a range of about 50 to about 65°, preferably about 54.7 to about 65°, the side face 114 may be regarded as including silicon substantially oriented along the {111} plane.

The gate structure 120 includes a gate pattern 130 formed on the surface 118 of the substrate 110, and spacing members formed on sidewalls of the gate pattern 130.

The gate pattern 130 includes a gate insulation layer pattern 132 formed on the surface 118 of the substrate 110, a conductive layer pattern 134 formed on the gate insulation layer pattern 132, and a hard mask layer pattern 136 formed on the conductive layer pattern 134.

A portion of the surface 118 of the substrate 110 beneath the gate insulation layer pattern 132 serves as a channel layer that selectively and electrically connects one impurity region to another impurity region.

The gate insulation layer pattern 132 may include silicon oxide, silicon oxynitride, metal oxide, metal oxynitride, etc. The conductive layer pattern 134 may include a metal such as tungsten (W), copper (Co), aluminum (Al), metal nitride, etc. In addition, the hard mask layer pattern 136 may include silicon nitride.

Each of the spacing members may have a double spacer structure. That is, each of the spacing members includes first spacers 142 and second spacers 144. The first spacers 142 are formed on the sidewalls of the gate pattern 130 and the second spacers 144 are positioned on the first spacers 142. Since the spacing members assure a sufficient channel length of the transistor 100, a short channel effect generated in the transistor 100 may be prevented. Particularly, the side faces 114 of the recesses 112 are between the gate pattern 130 and the second spacers 144. The first and second spacers 142 and 144 may include a substantially identical material, for example, silicon nitride. Alternatively, the first and second spacers 142 and 144 may include different materials from each other. For example, the first spacers 142 may include an oxide, whereas the second spacers 144 may include a nitride. Furthermore, each of the spacing members may have a single spacer structure.

The epitaxial layers 150 are formed in the recesses 112, respectively. The epitaxial layers 150 may include silicon germanium. Silicon germanium films grow from the side faces 114 and the bottom faces 116 of the recesses 112 to thereby form the epitaxial layers 150 filling up the recesses 112. As a result, each epitaxial layer 150 has a side face of the {111} plane and a bottom face of the {100} plane so that the epitaxial layer 150 may have a heterogeneous structure.

Impurities are implanted into the epitaxial layers 150 to form the impurity regions in the epitaxial layers 150. The impurities may include carbon (C), boron (B), phosphorous (P), etc. According to the present embodiment, each of the impurity regions has an area substantially identical to that of the epitaxial layer 150. Thus, each impurity region may have a side face substantially corresponding to that of the epitaxial layer 150.

Hereinafter, a method of manufacturing the transistor in FIG. 1 will be described in detail with reference to the accompanying drawings.

FIGS. 2 to 5 are cross sectional view illustrating the method of manufacturing the transistor in FIG. 1.

Referring to FIG. 2, the gate pattern 130 is formed on the surface 118 of the {100} crystal plane. The substrate 110 may correspond to the silicon substrate or the silicon-germanium substrate. In particular, an insulation layer (not shown) is formed on the surface 118 of the substrate 110. The insulation layer may include an oxide. A conductive layer (not shown) is formed on the insulation layer. The conductive layer may include a metal such as tungsten. A hard mask layer (not shown) is formed on the conductive layer. The hard mask layer may include a nitride such as silicon nitride. A photoresist pattern (not shown) is formed on the hard mask layer. The hard mask layer, the conductive layer and the insulation layer are partially etched using the photoresist pattern as an etching mask to thereby form the gate pattern 130 on the surface 118 of the substrate 110. The gate pattern 130 includes the insulation layer pattern 132, the conductive layer pattern 134 and the hard mask layer pattern 136. Then, the photoresist pattern on the gate pattern is removed by an ashing process and/or a stripping process.

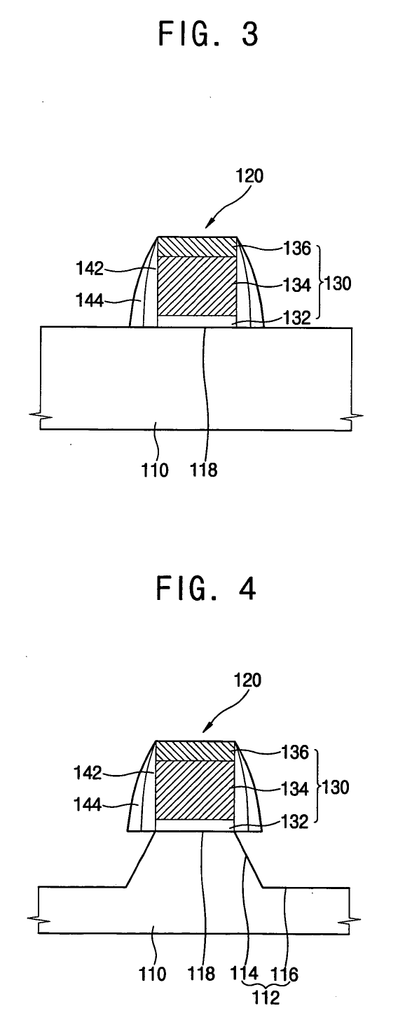

Referring to FIG. 3, a first nitride layer (not shown) is formed on the substrate 110 to cover the gate pattern 130. The first nitride layer is partially etched to form the first spacers 142 on the sidewalls of the gate pattern 130. For example, the first nitride layer includes silicon nitride.

A second nitride layer (not shown) is then formed on the substrate 110 to cover the gate pattern 130 and the first spacers 142. For example, the second nitride layer includes silicon nitride. The second nitride layer is partially etched to form the second spacers 144 on the first spacers 142, respectively. Thus, the spacing members including the first and second spacers 142 and 144 are formed on the sidewalls of the gate pattern 130. As a result, the gate structure 120 including the gate pattern 130 and the spacing members is formed on the substrate 110.

Referring to FIG. 4, the portions of the substrate 110 adjacent to the both sides of the gate structure 120 are partially etched to form the recesses 112 that have the side faces 114 of the {111} crystal plane and the bottom faces 116 of the {100} crystal plane. The portions of the substrate 110 may be etched by a dry etching process using an etching gas that includes hydrogen chloride (HCl). When the recesses 112 are formed, bottom faces of the first and second spacers 142 and 144 are exposed through the recesses 112.

In general, a method of etching a silicon-based material in a deposition chamber using an HCl gas has been widely used. In the present embodiment, the HCl gas etches not the silicon-based material but the portions of the substrate 110 including silicon in a deposition chamber. Therefore, the etching process of the present embodiment may not demand any additional etching chamber except for the deposition chamber. In addition, the HCl gas may be massively produced and widely used so that the etching process for partially etching the substrate 110 may be carried out stably and simply. Furthermore, since successive etching processes and deposition processes may be performed in-situ, an intermediate process such as a cleaning process may be omitted, thereby greatly reducing the time required for manufacturing the transistor 120.

In the present embodiment, the portions of the substrate 110 may be etched at a temperature of about 850° C. under a partial pressure of the HCl gas of about 10 Torr. In addition, the etching gas may further include an additional gas containing hydrogen such as GeH₄, SiH₄, SiH₂Cl₂ (dichlorosilane: DCS), etc. When the etching gas includes the additional gas containing hydrogen, the additional gas containing hydrogen serves as a catalyst relative to the HCl gas, based on a thermal equilibrium between the gases. Hence, the HCl gas may rapidly etch silicon at the portions of the substrate 110 due to the thermal equilibrium between the etching reaction gases. When the etching gas includes the HCl gas and the additional gas containing hydrogen by a predetermined volume ratio, the etching gas may etch silicon by an etching rate of about 1 nm/second at a temperature of about 730° C. Thus, each of the recesses 112 may have a depth of above about 50 nm when the etching process is performed for about one minute.

The etching process of etching the portions of the substrate 110 may be carried out at a temperature of about 500 to about 850° C., preferably a temperature of about 500 to about 700° C. using an etching gas including the HCl gas and the gas containing hydrogen such as GeH₄, SiH₄, SiH₂Cl₂ gas, etc.

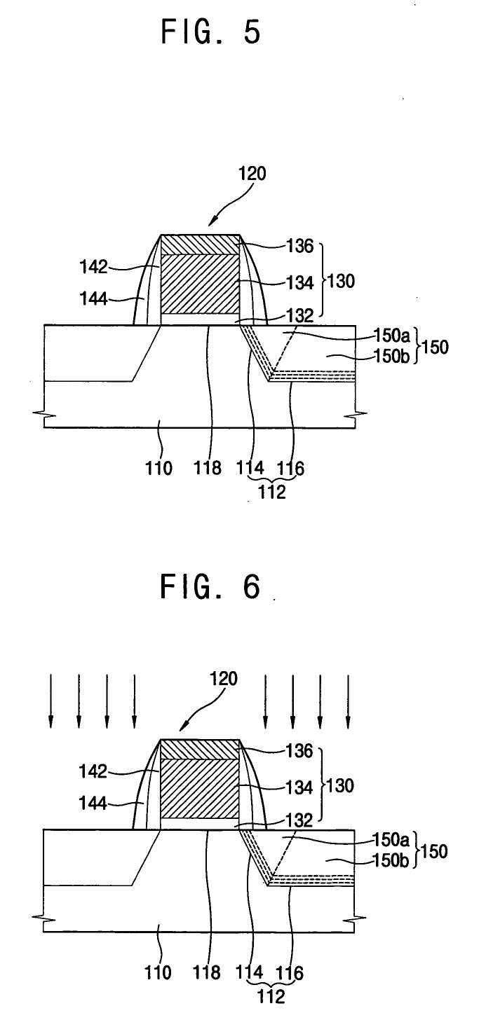

Referring to FIG. 5, a source gas containing silicon-germanium, for example, GeH₄, SiH₄ or SiH₂Cl₂ is introduced onto the recesses 112. Silicon-germanium in the source gas epitaxially grows from the side faces 114 and the bottom faces 116 of the recesses 112 to thereby form the epitaxial layers 150 respectively filling up the recesses 112 as shown phantom lines in FIG. 5. For example, the epitaxial layers 150 are formed to fill up the recesses 112 by a chemical vapor deposition (CVD) process. Here, since each recess 112 has the side face 114 of the {111} crystal plane and the bottom face 116 of the {100} plane, each of the epitaxial layers 150 has a hetero crystalline structure in which a first crystalline structure 150a grows from the side face 114 along the [111] direction, and a second crystalline structure 150b grows from the bottom face 116 in the [100] direction.

Alternatively, the source gas containing silicon-germanium and the impurities including carbon, boron or phosphorous may be simultaneously introduced onto the recesses 112 to thereby form the epitaxial layers 150 doped with the impurities.

As a result, the transistor 120 that includes the impurity regions each of which has the area substantially identical to that of the epitaxial layer 150 is formed on the substrate 110. That is, each impurity region may have a side boundary substantially corresponding to the side face of the epitaxial layer 150.

### Embodiment 2

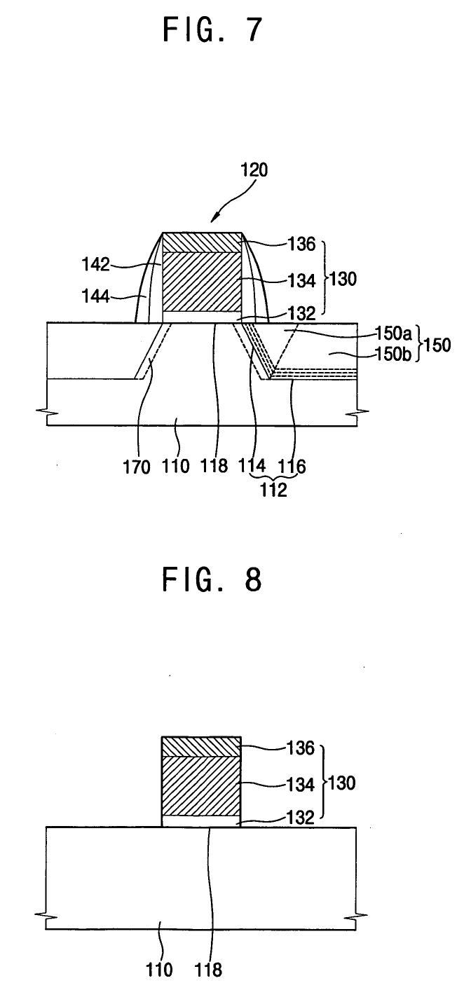

A transistor of a second embodiment of the present invention has elements substantially identical to those of the transistor in FIG. 1 except impurity regions 170 having side faces substantially different from those of epitaxial layers 150 as shown in FIG. 7. The side faces of the impurity regions 170 are respectively positioned between a central portion of a gate pattern 130 and side faces of the epitaxial layers 150. Thus, any further detailed description concerning the transistor of the present embodiment will not be repeated.

FIGS. 6 and 7 are cross sectional views illustrating a method for manufacturing the transistor in accordance with the present embodiment. In the present embodiment, processes for manufacturing the transistor are substantially identical to those described with reference to FIGS. 2 to 5 except a process for forming the impurity regions 170.

Referring to FIG. 6, impurities including carbon, boron, phosphorous, etc, are implanted into the epitaxial layers 150 by an ion implantation process as shown by the arrows in the figure. In Embodiment 1, the source gas and the impurities are simultaneously provided in recesses 112 to form the epitaxial layers 150 doped with the impurities in Embodiment 1. However, according to the present embodiment, after undoped epitaxial layers 150 grow to fill up the recesses 112, the impurities are additionally implanted into the undoped epitaxial layers 150.

Referring to FIG. 7, the substrate 110 having the epitaxial layers 150 is thermally treated so that the impurities in the epitaxial layers 150 are diffused to form the impurity regions 170. The impurity regions 170 correspond to source/drain regions of the transistor. The source/drain regions are adjacent to both sides of a gate structure 120. Thus, the transistor including the gate structure 120 and the impurity regions 170 is formed on the substrate 110.

As described above, the impurity regions 170 have the side faces substantially different from those of the epitaxial layers 150. Each of the side faces of the impurity regions 170 is positioned between the central portion of the gate pattern 130 and the side face of the epitaxial layer 150. The impurity regions 170 having such side faces are formed by diffusing the impurities into the substrate 110 through a heat treatment process for annealing the substrate 110. Alternatively, the impurity regions 170 may have side faces substantially identical to those of the epitaxial layers 150 as described above.

### Embodiment 3

A transistor of a third embodiment of the present invention has a structure substantially identical to that of the transistor in FIG. 1. Thus, a method of manufacturing the transistor of the present embodiment will be described with reference to FIGS. 8 to 12.

FIGS. 8 to 12 are cross sectional views illustrating the method of manufacturing the transistor according to the third embodiment of the present invention. In the present embodiment, after first spacers 142 are formed on sidewalls of a gate pattern 130, epitaxial layers 150 are formed in recesses 112 before second spacers 144 are formed on the first spacers 142.

Referring to FIG. 8, the gate pattern 130 including an insulation layer pattern 132, a conductive layer pattern 134 and a hard mask layer pattern 136 are formed on a surface 118 of a semiconductor substrate 110. The surface 118 includes silicon oriented along the {100} plane.

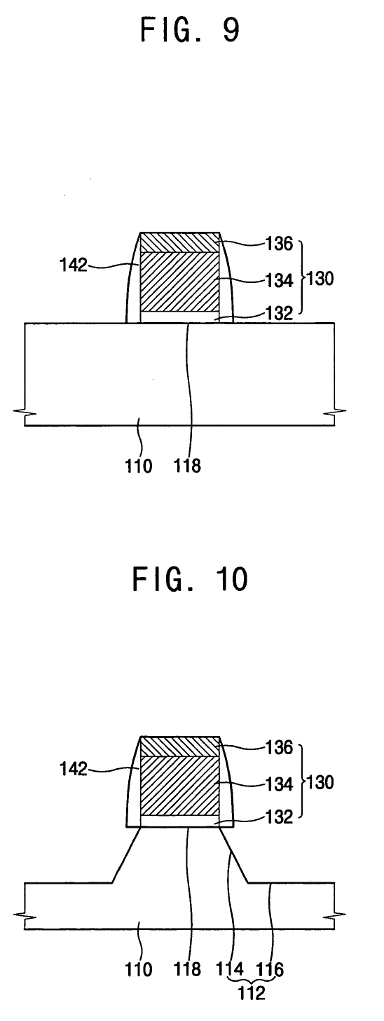

Referring to FIG. 9, the first spacers 142 including a nitride are formed on the sidewalls of the gate pattern 130, respectively. For example, the first spacers 142 include silicon nitride.

Referring to FIG. 10, portions of the surface 118 adjacent to both sides of the gate pattern 130 are etched to thereby form the recesses 112 at the portions of the surface 118. The recesses 112 may be formed by a dry etching process using an etching gas. The etching gas may include HCl and one of GeH₄, SiH₄ and SiH₂Cl₂. The dry etching process for forming the recesses 112 may be carried out under etching conditions substantially identical to those described in Embodiment 1. The recesses 112 have side faces 114 of the {111} plane and bottom faces 116 of the {100} plane. When the recesses 112 are formed by partially etching the substrate 110, bottom faces of the first spacers 142 are exposed through the recesses 112.

Referring to FIG. 11, a source gas containing silicon-germanium is introduced onto the recesses 112. Silicon-germanium epitaxially grows from the side faces 114 and the bottom faces 116 of the recesses 112 to thereby form the epitaxial layers 150 in the recesses 112, respectively. Since each recess 112 has the side face 114 of the {111} plane and the bottom face 116 of the {100} plane, each of the epitaxial layers 150 has a hetero structure in which a first crystalline structure 150a grows from the side face 114 in the [111] direction, and a second crystalline structure 150b grows from the bottom face 116 in the [100] direction. Alternatively, the source gas containing silicon-germanium and impurities including carbon, boron or phosphorous may be simultaneously introduced onto the recesses 112 to form the epitaxial layers 150 doped with the impurities.

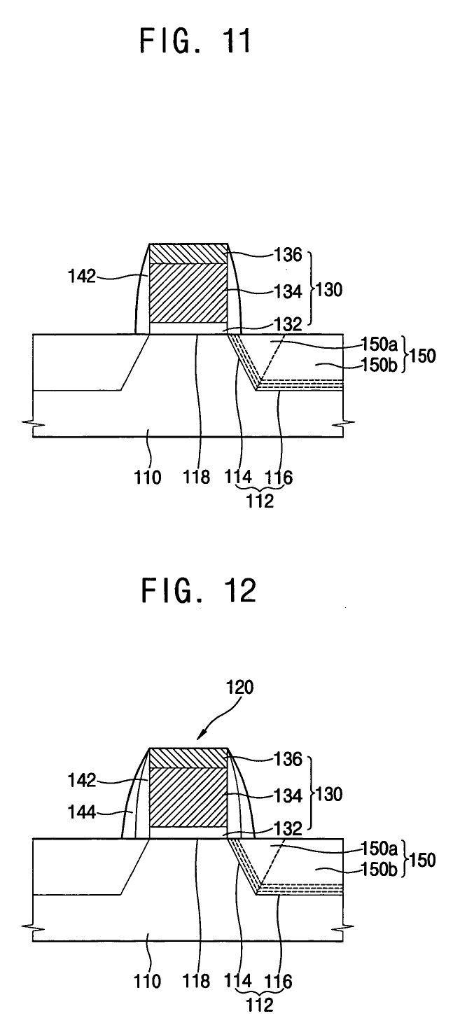

Referring to FIG. 12, the second spacers 144 including nitride are respectively formed on the first spacers to form spacing members on the sidewalls of the gate pattern 130. The spacing members include the first spacers 142 and the second spacers 144. Thus, a gate structure 120 including the gate pattern 130 and the spacing members are formed on the substrate 110. For example, the second spacers 144 include silicon nitride. Bottom portions of the second spacers 144 are respectively positioned on the epitaxial layers 150. Therefore, impurity regions of the transistor have boundaries substantially identical to those of the epitaxial layers 150. Particularly, each of the impurity regions has a side face substantially corresponding to that of the epitaxial layer 150.

Alternatively, the impurities including carbon, boron or phosphorous may be implanted into the epitaxial layers 150 to form the impurity regions having the side faces different from those of the epitaxial layers 150. Each side face of the impurity region is positioned between a central portion of the gate pattern 130 and the side face of the epitaxial layer 150.

### Embodiment 4

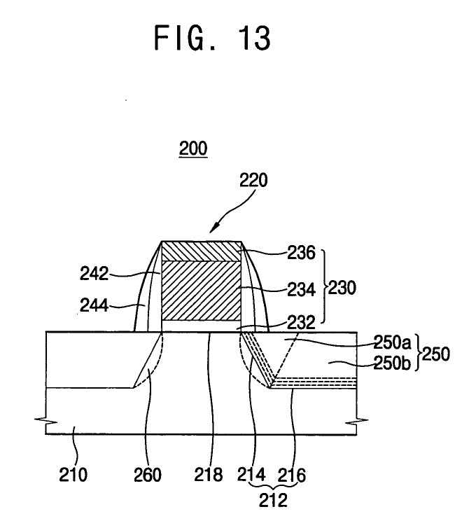

Referring to FIG. 13, a transistor 200 of a fourth embodiment of the present invention includes a semiconductor substrate 210, a gate structure 220 formed on the semiconductor substrate 210, two epitaxial layers 250 formed adjacent to both sides of the gate structure 220, impurity regions formed in the epitaxial layers 150, and halo implantation regions 260.

The semiconductor substrate 210 has a surface 218 of the {100} crystal plane. Two recesses 212 are formed at portions of the surface 218 adjacent to sidewalls of the gate structure 220. Each of the recesses 212 includes a bottom face 216 of the {100} crystal plane and side face 214 of the {111} crystal plane. The bottom face 216 has a height substantially less than that of the surface 218. The side face 214 connects the bottom face 216 to the surface 218.

The gate structure 220 includes a gate pattern 230 formed on the surface 218, and spacing members formed on sidewalls of the gate pattern 230. The gate pattern 230 includes a gate insulation layer pattern 232 formed on the surface 218, a conductive layer pattern 234 formed on the gate insulation layer pattern 232, and a hard mask layer pattern 236 formed on the conductive layer pattern 234. The spacing members may have dual spacer structures that include first spacers 242 formed on the sidewalls of the gate pattern 230, and second spacers 244 formed on the first spacers 242. Each side face 214 of the recess 212 is positioned between a central portion of the gate pattern 230 and the second spacer 244.

The epitaxial layers 250 including silicon-germanium are formed in the recesses 212. The epitaxial layers 250 have side faces of the {111} plane and bottom faces of the {100} plane, respectively.

Impurities are implanted into the epitaxial layers 250 to form the impurity regions in the epitaxial layers 250. The impurity regions of the present embodiment have side faces substantially corresponding to those of the epitaxial layers 150.

The halo implantation regions 260 are formed in portions of the semiconductor substrate 210 adjacent to the side faces 214 of the recesses 212. Thus, the halo implantation regions 260 partially make contact with the side faces of the epitaxial layers 250. The halo implantation regions 260 have conductivity types substantially different from those of the impurity regions to thereby prevent impurities in the impurity regions from diffusing into the semiconductor substrate 210.

Hereinafter, a method of forming the transistor in FIG. 13 will be described in detail with reference to FIGS. 14 to 19.

FIGS. 14 to 19 are cross sectional views illustrating the method of manufacturing the transistor in accordance with the present embodiment.

Referring to FIG. 14, the gate pattern 230 including the gate insulation layer pattern 232, the conductive layer pattern 234 and the hard mask layer pattern 236 is formed on the surface 218 including silicon arranged along the {100} plane as described above.

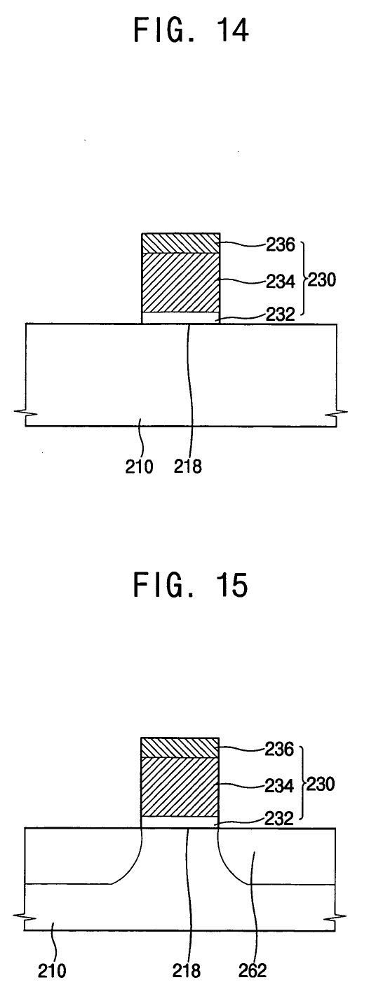

Referring to FIG. 15, halo dopants are implanted into the portions of the semiconductor substrate 210 adjacent to both sides of the gate pattern 230 so that preliminary halo implantation regions 262 are formed at the portions of the substrate 210. The preliminary halo implantation regions 262 have conductivity types substantially corresponding to that of the semiconductor substrate 210. Before forming the preliminary halo implantation regions 262, impurities may be implanted into the portions of the semiconductor substrate 210 with a relatively low concentration to thereby form lightly doped drain (LDD) regions (not shown) at the portions of the substrate 210.

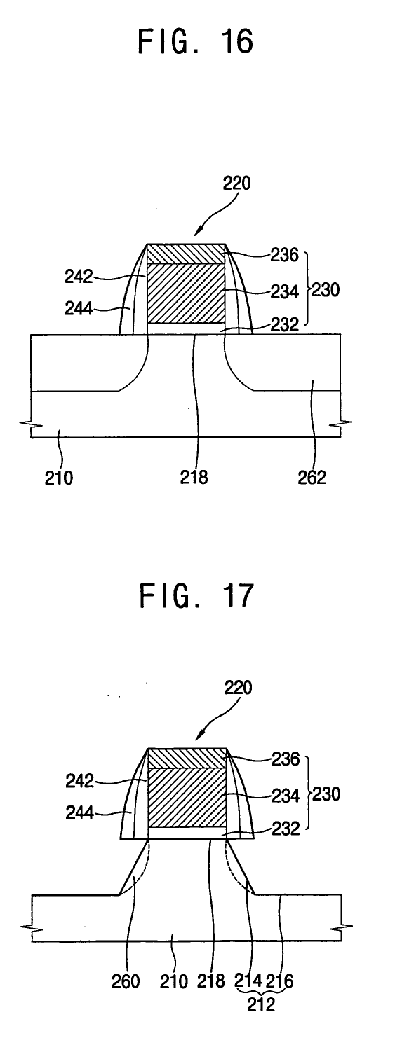

Referring to FIG. 16, the first spacers 242 are formed on the sidewalls of the gate pattern 230. Then, the second spacers 244 are formed on the first spacers 242 to form the spacing members on the sidewalls of the gate pattern 230. The first and second spacers 242 and 244 may include a nitride such as silicon nitride. Hence, the gate structure 220 including the gate pattern 230 and the first and second spacers 242 and 244 is formed on the substrate 210.

Referring to FIG. 17, the preliminary halo implantation regions 262 are partially etched to form the recesses 212 having the side faces 214 of the {111} plane and the bottom faces 216 of the {100} plane. Here, the halo implantation regions 260 are formed adjacent to the side faces 214 of the recesses 212. That is, remaining preliminary halo implantation regions 262 respectively correspond to the halo implantation regions 260. When the recesses 212 are formed, bottom faces of the first and second spacers 242 and 244 are exposed through the recesses 212. The halo implantation regions 260 make contact with the side faces 214 of the recesses 212. The preliminary halo implantation regions 262 may be etched using an etching gas that includes HCl and at least one of GeH₄, SiH₄ and SiH₂Cl₂. The etching process of etching the preliminary halo implantation regions 262 is performed under an etching condition substantially identical to that of the etching process according to Embodiment 1.

In the present embodiment, a chemical reaction between silicon and HCl in the preliminary halo implantation regions 262 may more actively occur in comparison with other portions of the semiconductor substrate 210 in which the halo dopants do not exist. The preliminary halo implantation regions 262 may be rapidly etched in a vertical direction relative to the substrate 210 so that a time of forming the recesses 212 in the preliminary halo implantation regions 262 may be shortened along the vertical direction. As a result, the side faces 214 of the {111} plane may be readily formed beneath the spacing members.

Referring to FIG. 18, a source gas including silicon-germanium is introduced onto the recess 212. Silicon-germanium epitaxially grows from the side faces 214 and the bottom faces 216 of the recesses 212 to respectively form the epitaxial layers 250 in the recesses 212. Since the recesses 212 have the side faces 214 of the {111} plane and the bottom faces 216 of the {100} plane, the epitaxial layers 250 have hetero structures in which first crystalline structures 250a grow from the side faces 214 in the [111] direction, and second crystalline structures 250b grow from the bottom faces 216 in the [100] direction. The source gas containing silicon-germanium and the impurities including carbon, boron or phosphorous may be simultaneously introduced onto the recesses 212 to thereby form the epitaxial layers 250 doped with the impurities.

As a result, impurity regions of the transistor 200 have boundaries substantially corresponding to the side faces of the epitaxial layers 150.

Each of the impurity regions has a conductivity type substantially different from that of the halo implantation region 260. For example, when the halo implantation regions 260 have P types, the impurity regions have N types and vice versa. Since the halo implantation regions 260 have conductivity types different from those of the impurity regions, the halo implantation regions 260 suppress the diffusion of the impurities into the semiconductor substrate 210. Thus, a short channel effect of the transistor 200 generated by adjacently disposing a source region and a drain region of the transistor 200 may be effectively prevented.

### Embodiment 5

A transistor of a fifth embodiment of the present invention has elements substantially identical to those of the transistor in FIG. 13 except impurity regions 270 having side faces different from those of epitaxial layers 250. Each side face of the impurity region 270 is positioned between a central portion of a gate pattern 230 and side faces of the epitaxial layers 250. Thus, any further detailed description of the transistor of the present embodiment will not be repeated.

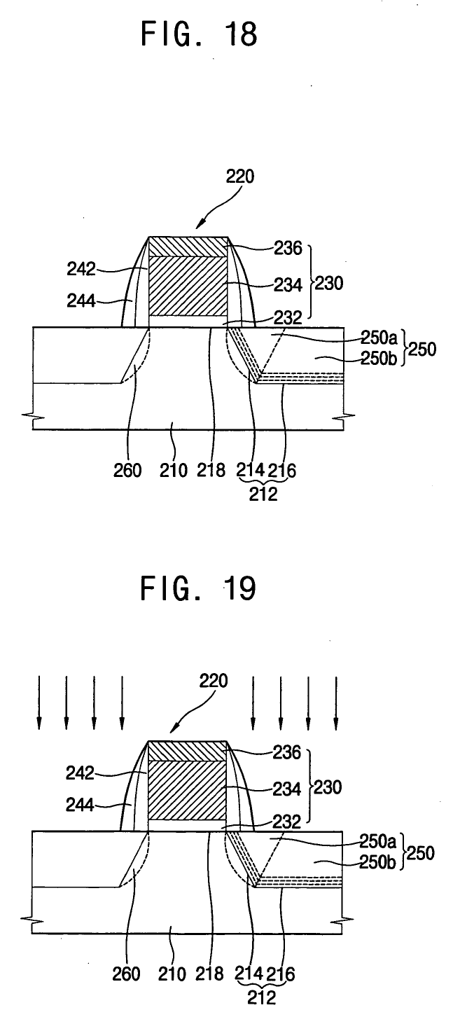

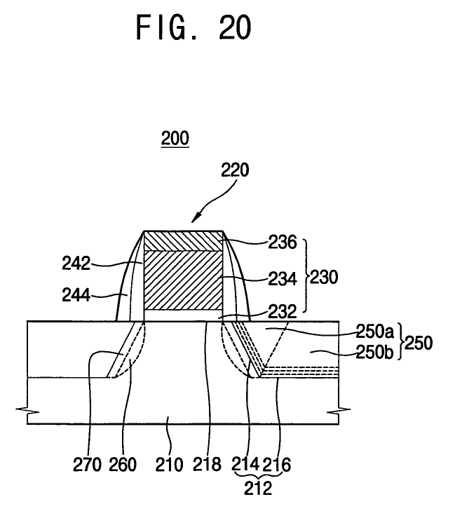

FIGS. 19 and 20 are cross sectional views illustrating a method of manufacturing the transistor according to the present embodiment. In the present embodiment, processes of forming the transistor are substantially identical to those of the fourth embodiment illustrated with reference to FIGS. 14 to 18 except a process for forming impurity regions 270 (see FIG. 20). Therefore, processes after forming epitaxial layers 250 will be described in detail.

Referring to FIG. 19, impurities including carbon, boron or phosphorous are implanted into the epitaxial layers 250 by an ion implantation process. In Embodiment 4, the source gas and the impurities are simultaneously provided onto the recesses 212 to form the doped epitaxial layers 250. However, according to the present embodiment, after undoped epitaxial layers 250 grow to fill up the recesses 212, the impurities are implanted into the undoped epitaxial layers 250.

Referring to FIG. 20, a substrate 210 having the doped epitaxial layers 250 are thermally treated to form the impurity regions 270 in the epitaxial layers 250, respectively. The impurity regions 270 correspond to source/drain regions of the transistor. When the impurity regions 270 are formed adjacent to both sides of a gate structure 220, the transistor is completed on the substrate 210.

In the present embodiment, the impurity regions 270 have side faces different from those of the epitaxial layers 250 as described above. That is, each side face of the impurity region 270 is positioned between a central portion of a gate pattern 230 and the side face of the epitaxial layer 250. The impurity regions 270 having such side faces are formed by diffusing the impurities into the semiconductor substrate 210 through an annealing process for thermally treating the substrate 210. Alternatively, the impurity regions 270 may have side faces substantially corresponding to those of the epitaxial layers 250.

### Embodiment 6

A transistor of a sixth embodiment of the present invention has a structure substantially identical that of the transistor in FIG. 13. Thus, any further detailed description with regard to the structure of the transistor will not be repeated.

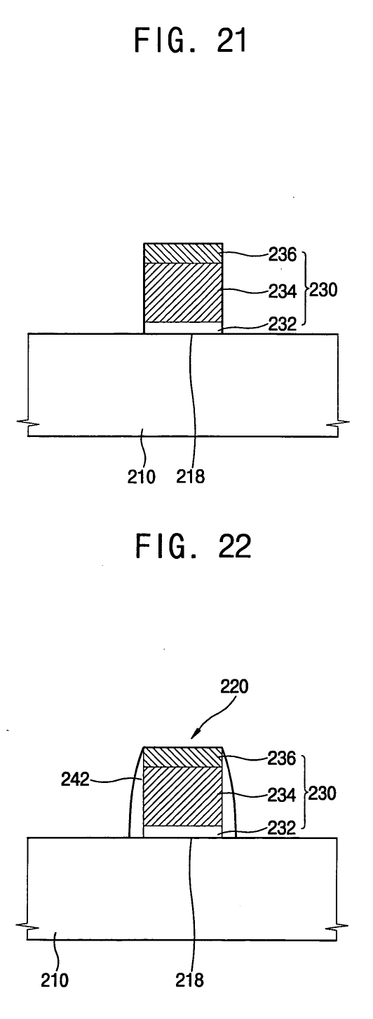

FIGS. 21 to 26 are cross sectional views illustrating a method of manufacturing the transistor in accordance with the present embodiment. In the present embodiment, after first spacers 242 are formed on sidewalls of a gate pattern 230, epitaxial layers 250 are formed before second spacers 244 are formed on the first spacers 242.

Referring to FIG. 21, the gate pattern 230 including a gate insulation layer pattern 232, a conductive layer pattern 234 and a hard mask layer pattern 236 is formed on a surface 218 of a semiconductor substrate 210. The surface 218 includes silicon oriented along the {100} plane.

Referring to FIG. 22, the first spacers 242 are respectively formed on the sidewalls of the gate pattern 230. For example, the first spacers 242 are formed using a nitride such as silicon nitride.

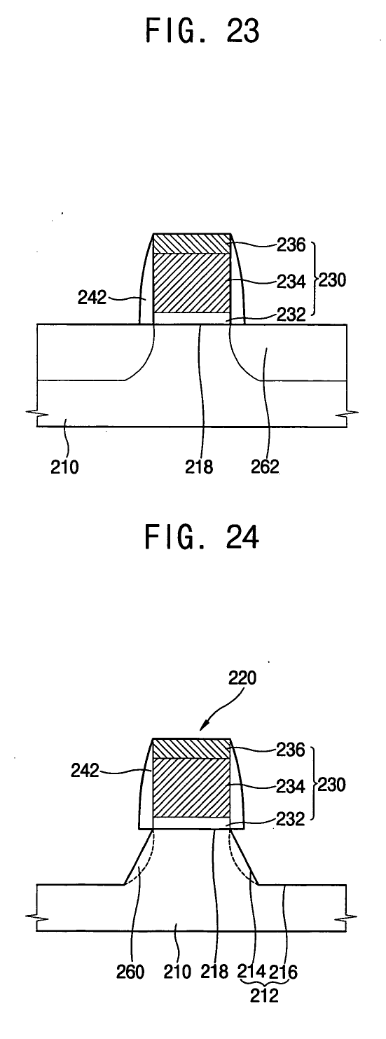

Referring to FIG. 23, halo dopants are implanted into portions of the semiconductor substrate 210 adjacent to both sides of the gate pattern 230 using the first spacers 242 as ion implantation masks, thereby forming preliminary halo implantation regions 262 at the portions of the substrate 210. The preliminary halo implantation regions 262 have conductivity types substantially identical to that of the semiconductor substrate 210. Before forming the preliminary halo implantation regions 262, impurities may be implanted into the portions of the substrate 210 with a relatively low concentration so that LDD regions (not shown) may be formed at the portions of the substrate 210.

Referring to FIG. 24, the preliminary halo implantation regions 262 are partially etched using an etching gas to form recesses 212 having side faces 214 of the {111} plane and bottom faces 216 of the {100} plane. Simultaneously, halo implantation regions 260 are formed adjacent to the side faces 214 of the recesses 212. Bottom faces of the first spacers 242 are exposed through the recesses 212. The halo implantation regions 260 make contact with the side faces 214 of the recesses 212. The etching gas may include HCl and at least one of GeH₄, SiH₄ and SiH₂Cl₂. An etching process of etching the preliminary halo implantation regions 262 is carried out under etching conditions substantially identical to those of Embodiment 1.

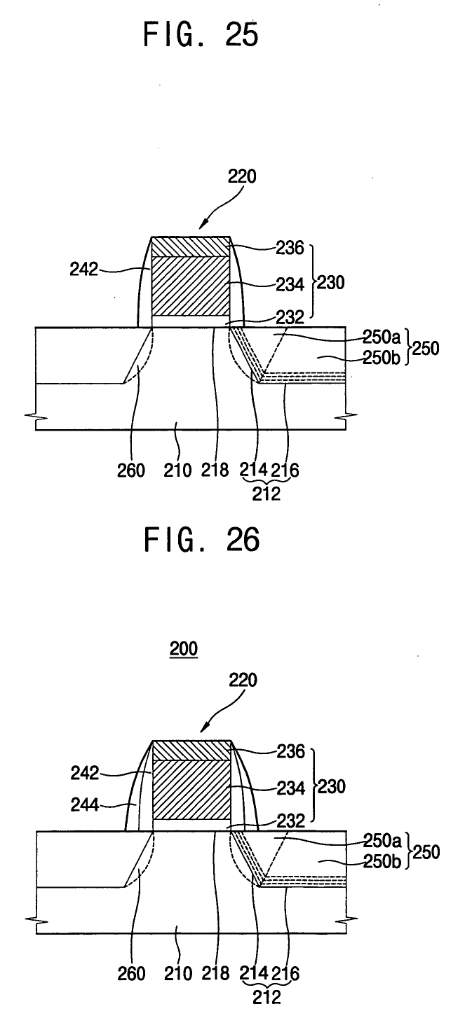

Referring to FIG. 25, a source gas containing silicon-germanium is introduced onto the recesses 212 so that silicon-germanium epitaxially grows from the side faces 214 and the bottom faces 216 of the recesses 212. Hence, the epitaxial layers 250 are formed to fill up the recesses 212. Because the recesses 212 have the side faces 214 of the {111} plane and the bottom faces 216 of the {100} plane, the epitaxial layers 250 have hetero structures in which first crystalline structures 250a grow from the side faces 214 in the [111] direction, and second crystalline structures 250b grow from the bottom faces 216 in the [100] direction, respectively.

The source gas containing silicon-germanium and the impurities including carbon, boron or phosphorous may be simultaneously introduced onto the recesses 212 to thereby form the epitaxial layers 250 doped with the impurities. The epitaxial layers 250 have boundaries substantially corresponding to those of the impurity regions.

Alternatively, the impurities including carbon, boron or phosphorous may be implanted into the epitaxial layers 250 to form the impurity regions 270 having side faces substantially different from those of the epitaxial layers 250. Each of the side faces of the impurity regions 270 is positioned between the central of the gate pattern 230 and the side face of the epitaxial layer 250.

Referring to FIG. 26, the second spacers 244 are formed on the first spacers 242 to form the spacing members on the sidewalls of gate pattern 230. Each second spacer 244 is formed using a nitride such as silicon nitride. Thus, the gate structure 220 having the spacing members and the gate pattern 230 is formed on the substrate 210. The second spacers 244 are respectively positioned on the epitaxial layers 250. Then, the second spacers 244 are formed, and thus the transistor of the present embodiment is completed on the substrate 210.

### Embodiment 7

A transistor of a seventh embodiment of the present invention includes elements substantially identical those of the transistor in Embodiment 1 except elevated epitaxial layers. Thus, any further detailed description concerning the transistor of the present embodiment will not be repeated.

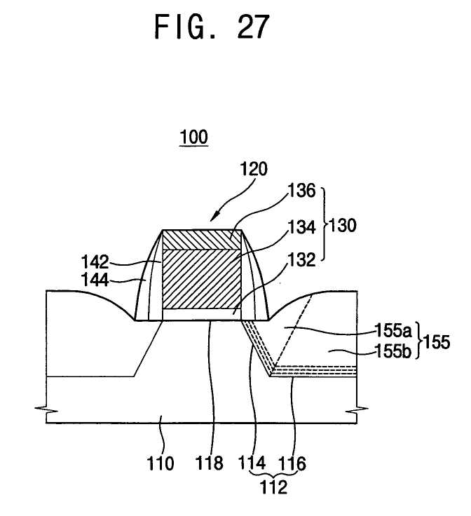

FIG. 27 is a cross sectional view illustrating the transistor in accordance with the present embodiment.

Referring to FIG. 27, the elevated epitaxial layers 155 have surfaces higher than a surface 118 of a semiconductor substrate 110 although the epitaxial layers 150 have surfaces substantially identical to the surface 118 of the semiconductor substrate 110 in Embodiment 1.

In the present embodiment, a method of manufacturing the transistor is substantially identical to the above method described with reference to FIGS. 2 to 4 except a process for forming the elevated epitaxial layers 155.

Referring now to FIG. 27, a source gas containing silicon-germanium, for example, a gas including GeH₄, SiH₄ or SiH₂Cl₂ is introduced onto recesses 112 for a relatively long time in comparison with Embodiment 1. Silicon-germanium epitaxially grows from the side faces 114 and the bottom faces 116 of the recesses 112 so that the elevated epitaxial layers 155 are formed to fill up the recesses 112 and upwardly extended. Each of the elevated epitaxial layer 155 has a hetero structure in which a first crystalline structure 155a grows from the side face 114 in the [111] direction, and a second crystalline structure 155b grows from the bottom face 116 in the [100] direction. Also, the elevated epitaxial layers 155 have the surfaces higher than the surface 118 of the semiconductor substrate 110.

Alternatively, the source gas containing silicon-germanium and impurities including carbon, boron or phosphorous may be simultaneously introduced onto the recesses 112 to thereby form the elevated epitaxial layers 155 doped with the impurities.

As a result, the transistor 100 is formed on the substrate 110 to include impurity regions that have boundaries substantially corresponding to the side faces of the elevated epitaxial layers 155. The impurity regions may correspond to source/drain regions of the transistor 100.

Alternatively, after the elevated epitaxial layers 155 are formed without doping the impurities therein as described above, the impurities are implanted into the elevated epitaxial layer 155 to thereby form elevated impurity regions corresponding to source/drain regions.

According to the present invention, epitaxial layers have hetero structures in which first crystalline structures grow from side faces of the {111} plane in the [111] direction, and second crystalline structures grow from bottom faces of the {100} plane in the [100] direction. Therefore, impurity regions of a transistor may have side faces of the {111} plane so that a short channel effect generated between the impurity regions may be prevented.

While this invention has been particularly shown and described with references to preferred embodiments thereof, it will be understood by those skilled in the art that various changes in form and details may be made herein without departing from the spirit and scope of the invention as defined by the appended claims.

What is claimed is:

1. A transistor comprising:
a semiconductor substrate having a first surface of a {100} crystal plane, a second surface of a {100} crystal plane having a height lower than that of the first surface, and a side face of a {111} crystal plane connecting the first surface to the second surface;
a gate structure formed on the first surface;
an epitaxial layer formed on the second surface and the side face; and
impurity regions formed adjacent to both sides of the gate structure.

2. The transistor of claim 1, wherein the gate structure comprises:
a gate insulation layer pattern formed on the first surface; and
a conductive pattern formed on the gate insulation layer pattern.

3. The transistor of claim 2, further comprising a hard mask layer pattern formed on the conductive layer pattern.

4. The transistor of claim 2, further comprising a spacing member formed on a sidewall of the conductive layer pattern.

5. The transistor of claim 4, wherein the side face is positioned beneath the spacing member.

6. The transistor of claim 4, wherein the spacing member comprises:
a first spacer formed on the sidewall of the conductive layer pattern; and
a second spacer formed on the first spacer.

7. The transistor of claim 6, wherein the first and second spacers comprise a substantially identical material.

8. The transistor of claim 7, wherein the first and second spacers comprise a nitride.

9. The transistor of claim 1, wherein the epitaxial layer comprises silicon-germanium.

10. The transistor of claim 1, wherein the impurity regions comprise side faces substantially corresponding to the side face of the semiconductor substrate.

11. The transistor of claim 1, wherein the impurity regions comprise side faces between the side face of the semiconductor substrate and a central portion of the gate structure.

12. The transistor of claim 1, wherein the impurity regions are doped with carbon, boron or phosphorous.

13. The transistor of claim 1, further comprising a halo implantation region formed at a portion of the semiconductor substrate adjacent to the side face of the semiconductor substrate, the halo implantation region preventing impurities in the impurity regions from diffusing into the semiconductor substrate.

14. The transistor of claim 13, wherein the halo implantation region comprises a conductive type substantially different from those of the impurity regions.

15. The transistor of claim 1, wherein the epitaxial layer comprises a first crystalline structure growing from the side face of the {111} crystal plane in the [111] direction, and a second crystalline structure growing from the second surface of the {100} crystal plane in the [100] direction.

16. The transistor of claim 1, wherein the epitaxial layer comprises a surface higher than the first surface of the semiconductor substrate.

17. A transistor comprising:
a semiconductor substrate having a first surface of a {100} crystal plane, two second faces of the {100} crystal plane having heights lower than that of the first surface, and two side faces of a {111} crystal plane connecting the first surface to the second surface faces;
a gate pattern formed on the first surface;
two epitaxial layers formed on the second faces and the side faces, respectively; and
two impurity regions respectively formed in the epitaxial layers.

18. The transistor of claim 17, wherein spacing members are formed on sidewalls of the gate pattern.

19. The transistor of claim 18, wherein the side faces are beneath the spacing members.

20. The transistor of claim 17, wherein the epitaxial layers comprise silicon-germanium.

21. The transistor of claim 17, wherein the impurity regions comprise side faces substantially corresponding to the side faces of the semiconductor substrate.

22. The transistor of claim 17, wherein the impurity regions comprise side faces between the side faces of the semiconductor substrate and a central portion of the gate structure.

23. The transistor of claim 17, wherein the impurity regions are doped with carbon, boron or phosphorous.

24. The transistor of claim 17, further comprising halo implantation regions respectively formed at portions of the semiconductor substrate that make contact with the side faces of the semiconductor substrate, the halo implantation regions preventing impurities in the impurity regions from diffusing into the semiconductor substrate.

25. The transistor of claim 24, wherein the halo implantation regions comprise conductive types substantially different from those of the impurity regions.

26. The transistor of claim 17, wherein the epitaxial layers comprise first crystalline structures growing from the side faces of the {111} crystal plane in the [111] direction, and second crystalline structures growing from the second surfaces of the {100} crystal plane in the [100] direction.

27. The transistor of claim 17, wherein the epitaxial layers comprise surfaces higher than the first surface of the semiconductor substrate.

28. A method of manufacturing a transistor comprising:
providing a semiconductor substrate having a first surface of a {100} crystal plane, a second surface of the {100} crystal plane having a height lower than that of the first surface, and a side face of a {111} crystal plane connecting the first surface to the second surface;
forming a gate structure on the first surface;
growing an epitaxial layer on the second surface and the side face; and
implanting impurities into the epitaxial layer to form impurity regions.

29. The method of claim 28, wherein forming the gate structure comprises:
forming a gate insulation layer pattern on the first surface; and
forming a conductive pattern on the gate insulation layer pattern.

30. The method of claim 29, further comprising forming a hard mask layer pattern on the conductive layer pattern.

31. The method of claim 29, further comprising forming a spacing member on a sidewall of the conductive layer pattern.

32. The method of claim 31, wherein the side face is positioned beneath the spacing member.

33. The method of claim 31, wherein forming the spacing member comprises:
forming a first spacer on the sidewall of the conductive layer pattern; and
forming a second spacer on the first spacer.

34. The method of claim 33, wherein the first and second spacers comprise a substantially identical material.

35. The method of claim 34, wherein the first and second spacers comprise a nitride.

36. The method of claim 28, wherein the second surface and the side face are formed by partially etching the semiconductor substrate.

37. The method of claim 36, wherein the semiconductor substrate is partially etched using an etching gas that includes HCl and at least one of GeH₄, SiH₄ and SiH₂Cl₂.

38. The method of claim 36, wherein the semiconductor substrate is partially etched at a temperature of about 500 to about 700° C.

39. The method of claim 36, prior to partially etching the semiconductor substrate, further comprising implanting halo dopants into the semiconductor substrate to form a preliminary halo implant region, and partially removing the preliminary halo implantation region during partially etching the semiconductor substrate to form a halo implantation region making contact with the side face of the semiconductor substrate, the halo implantation region preventing the impurities from diffusing into the semiconductor substrate.

40. The method of claim 39, wherein the halo dopants comprise conductivity types substantially different from those of the impurity regions.

41. The method of claim 28, wherein the epitaxial layer comprises silicon-germanium.

42. The method of claim 28, wherein the epitaxial layer comprises a first crystalline structure growing from the side face of the {111} crystal plane in the [111] direction, and a second crystalline structure growing from the second surface of the {100} crystal plane in the [100] direction.

43. The method of claim 28, wherein the epitaxial layer comprises a surface higher than the first surface of the semiconductor substrate.

44. The method of claim 28, wherein implanting the impurities and growing the epitaxial layer are simultaneously performed.

45. The method of claim 28, wherein the impurities comprise carbon, boron or phosphorous.

46. A method of manufacturing a transistor comprising:
forming a gate pattern on a surface of a {100} crystal plane of a semiconductor substrate;
forming a first spacer on a sidewall of the gate pattern;
forming a second spacer on the first spacer;
etching portions of the semiconductor substrate adjacent to both sides of the gate pattern to form a recess including a bottom face of the {100} crystal plane having a height lower than that of the surface, and a side face of the {111} crystal plane connecting the surface to the bottom face, the recess exposing a portion of the gate pattern, the first spacer and the second spacer;
growing an epitaxial layer in the recess; and
implanting impurities into the epitaxial layer to form impurity regions.

47. The method of claim 46, wherein the side face is positioned beneath the first and second spacers.

48. The method of claim 46, prior to forming the second spacer, further comprising implanting halo dopants into the semiconductor substrate using the first spacer as an ion implantation mask to form a preliminary halo implantation region, and partially removing the preliminary halo implantation region during forming the recess to form a halo implantation region making contact with the side face, the halo implantation region preventing the impurities from diffusing into the semiconductor substrate.

49. The method of claim 46, wherein etching the portions of the semiconductor substrate is carried out using an etching gas that includes HCl and at least one of GeH₄, SiH₄ and SiH₂Cl₂.

50. The method of claim 46, wherein etching the portions of the semiconductor substrate is performed at a temperature of about 500 to about 700° C.

51. The method of claim 46, wherein the epitaxial layer comprises a surface higher than the surface of the semiconductor substrate.

52. The method of claim 46, wherein the epitaxial layer comprises silicon-germanium.

53. The method of claim 46, wherein implanting the impurities and growing the epitaxial layer are simultaneously performed.

54. A method of manufacturing a transistor comprising:
forming a gate pattern on a surface of a {100} crystal plane of a semiconductor substrate;
forming first spacers on sidewalls of the gate pattern;
partially etching portions of the semiconductor substrate adjacent to the sidewalls of the gate pattern to form recesses including bottom faces of the {100} crystal plane having height lower than that of the surface, and a side faces of the {111} crystal plane connecting the surface to the bottom faces, the recesses exposing a portion of the gate pattern and the first spacers;
growing epitaxial layers in the recesses, respectively;
forming second spacers on the first spacers and the epitaxial layers; and
implanting impurities into the epitaxial layers to form impurity regions.

55. The method of claim 54, prior to etching the portions of the semiconductor substrate, further comprising implanting halo dopants into the semiconductor substrate using the first spacers as ion implantation masks to form preliminary halo implantation regions, and partially removing the preliminary halo implantation regions during forming the recesses to form halo implantation regions making contact with the side faces of the recesses, the halo implantation regions preventing the impurities from diffusing into the semiconductor substrate.

56. The method of claim 54, wherein the epitaxial layers comprise surfaces higher than the surface of the semiconductor substrate.
